(19) United States
(12) Patent Application Publication
(10) Pub. No.: US 2026/0157241 A1
(43) Pub. Date: Jun. 4, 2026

(54) POWER COMPONENT HAVING PIN INSERTION CONFIGURATION AND SIGNAL TRANSMISSION ASSEMBLY THEREOF

(71) Applicant: TONG HSING ELECTRONIC INDUSTRIES, LTD., Taoyuan City (TW)

(72) Inventors: YAN-WEI CHEN, Taoyuan City (TW); Chih-Yu Chung, Taipei City (TW); CHIN-WEN CHANG, Taoyuan City (TW); Yu-Te Hsieh, Taoyuan City (TW)

(21) Appl. No.: 19/015,550

(22) Filed: Jan. 9, 2025

(30) Foreign Application Priority Data
Dec. 3, 2024 (TW) 113146669

(51) Int. Cl. H01L 23/498; H01L 23/31; H01R 12/58

(52) U.S. Cl. CPC H10W 90/701; H01R 12/585; H10W 70/65; H10W 74/114

(57) ABSTRACT

A signal transmission assembly of a power component includes a pin holder and a conductive pin that is inserted into the pin holder. The pin holder is integrally formed as a single one-piece tube structure and has a connection end portion, an insertion end portion, and a positioning segment that is arranged between the connection end portion and the insertion end portion. The insertion end portion has a first length and a first inner diameter, and the positioning segment has a second length being greater than the first length and a second inner diameter that is less than the first inner diameter. The conductive pin and the insertion end portion have a first interference value therebetween, and the conductive pin and the positioning segment have a second interference value therebetween that is greater than the first interference value.

### CROSS-REFERENCE TO RELATED PATENT APPLICATION

This application claims the benefit of priority to Taiwan Patent Application No. 113146669, filed on Dec. 3, 2024. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a power component, and more particularly to a power component having a pin insertion configuration and a signal transmission assembly thereof.

### BACKGROUND OF THE DISCLOSURE

In a conventional power component provided with a pin insertion configuration, a conductive pin can easily be bent when being inserted into a pin holder (i.e., a pin insertion process), such that a success rate of the pin insertion process of the conventional power component is difficult to meet expectations.

### SUMMARY OF THE DISCLOSURE

In response to the above-referenced technical inadequacies, the present disclosure provides a power component having a pin insertion configuration and a signal transmission assembly thereof for effectively improving on the issues associated with conventional power components.

In order to solve the above-mentioned problems, one of the technical aspects adopted by the present disclosure is to provide a power component having a pin insertion configuration, which includes a circuit board, a plurality of pin holders, and a plurality of conductive pins. The circuit board has a plurality of connection pads. Each of the pin holders is integrally formed as a single one-piece tube structure and has a penetrating slot along a longitudinal direction thereof. Each of the pin holders has a connection end portion, an insertion end portion, and a positioning segment. The connection end portion is fixed onto one of the connection pads. The insertion end portion is arranged away from the connection end portion. The insertion end portion has a first length along the longitudinal direction and a first inner diameter along a width direction perpendicular to the longitudinal direction. The positioning segment is arranged between the connection end portion and the insertion end portion. The positioning segment has a second length along the longitudinal direction and a second inner diameter along the width direction. The second length is greater than the first length, and the second inner diameter is less than the first inner diameter. Each of the conductive pins includes an insertion segment and a fixing segment that is connected to the insertion segment. The insertion segments of the conductive pins are respectively inserted into the positioning segments of the pin holders from the insertion end portions, such that each of the conductive pins is electrically coupled to a corresponding one of the connection pads. The insertion segment of each of the conductive pins and the insertion end portion of the corresponding pin holder have a first interference value therebetween along the width direction, and the insertion segment of each of the conductive pins and the positioning segment of the corresponding pin holder have a second interference value therebetween along the width direction. The second interference value is greater than the first interference value.

In order to solve the above-mentioned problems, another one of the technical aspects adopted by the present disclosure is to provide a signal transmission assembly of a power component, which includes a pin holder and a conductive pin. The pin holder is integrally formed as a single one-piece tube structure and has a penetrating slot along a longitudinal direction thereof. The pin holder has a connection end portion, an insertion end portion arranged away from the connection end portion, and a positioning segment that is arranged between the connection end portion and the insertion end portion. The insertion end portion has a first length along the longitudinal direction and a first inner diameter along a width direction perpendicular to the longitudinal direction. The positioning segment has a second length along the longitudinal direction and a second inner diameter along the width direction. The second length is greater than the first length, and the second inner diameter is less than the first inner diameter. The conductive pin includes an insertion segment and a fixing segment that is connected to the insertion segment. The insertion segment of the conductive pin is inserted into the positioning segment of the pin holder from the insertion end portion. The insertion segment of the conductive pin and the insertion end portion of the pin holder may optionally have a first interference value therebetween along the width direction, and the insertion segment of the conductive pin and the positioning segment of the pin holder have a second interference value therebetween along the width direction. The second interference value is greater than the first interference value.

In order to solve the above-mentioned problems, yet another one of the technical aspects adopted by the present disclosure is to provide a power component having a pin insertion configuration, which includes a circuit board, a plurality of pin holders, and a plurality of conductive pins. The circuit board has a plurality of connection pads. Each of the pin holders is integrally formed as a single one-piece tube structure and has a penetrating slot along a longitudinal direction thereof. The penetrating slot of each of the pin holders has a slot section perpendicular to the longitudinal direction. Each of the pin holders has a connection end portion fixed onto one of the connection pads, an insertion end portion arranged away from the connection end portion, and a positioning segment that is arranged between the connection end portion and the insertion end portion. Each of the conductive pins includes an insertion segment and a fixing segment that is connected to the insertion segment. The insertion segments of the conductive pins are respectively inserted into the positioning segments of the pin holders from the insertion end portions, such that each of the conductive pins is electrically coupled to a corresponding one of the connection pads. The insertion segment of each of the conductive pins has a front sub-segment and a rear sub-segment. The front sub-segment has a front section that is perpendicular to the longitudinal direction and that is smaller than the slot section. The rear sub-segment is connected to the front sub-segment and has a rear section that is perpendicular to the longitudinal direction and that is larger than the slot section. The front sub-segment of the insertion segment of each of the conductive pins and the corresponding pin holder have a gap therebetween along a width direction perpendicular to the longitudinal direction, and the rear sub-segment of the insertion segment of each of the conductive pins and the corresponding pin holder have an interference value therebetween along the width direction.

Therefore, the power component in the present disclosure is provided with a structural cooperation between each of the pin holders and the corresponding conductive pin, so that when the insertion segment is inserted into the pin holder (i.e., a pin insertion process), an interference between the insertion segment and the pin holder can be gradually increased (e.g., the insertion segment is cooperated with the insertion end portion by the smaller first interference value, and then the insertion segment is further cooperated with the positioning segment by the larger second interference value; or, the front sub-segment is cooperated with the pin holder for jointly forming the gap, and then the rear sub-segment is interfered with the pin holder), thereby enabling the conductive pin to be firmly inserted into the pin holder and effectively preventing the conductive pin from being bent in the pin insertion process.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic cross-sectional view of a power component having a pin insertion configuration according to a first embodiment of the present disclosure;

FIG. 2 is a schematic enlarged view of part II of FIG. 1;

FIG. 3 is a first alternative configuration of the power component of FIG. 2;

FIG. 4 is a second alternative configuration of the power component of FIG. 2;

FIG. 5 is a third alternative configuration of the power component of FIG. 2;

FIG. 6 is a schematic cross-sectional view of the power component according to a second embodiment of the present disclosure;

FIG. 7 is a schematic cross-sectional view of the power component according to a third embodiment of the present disclosure;

FIG. 8 is a schematic cross-sectional view taken along line VIII-VIII of FIG. 7;

FIG. 9 is a schematic cross-sectional view taken along line IX-IX of FIG. 7; and

FIG. 10 is a schematic cross-sectional view showing the power component in another configuration according to the third embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

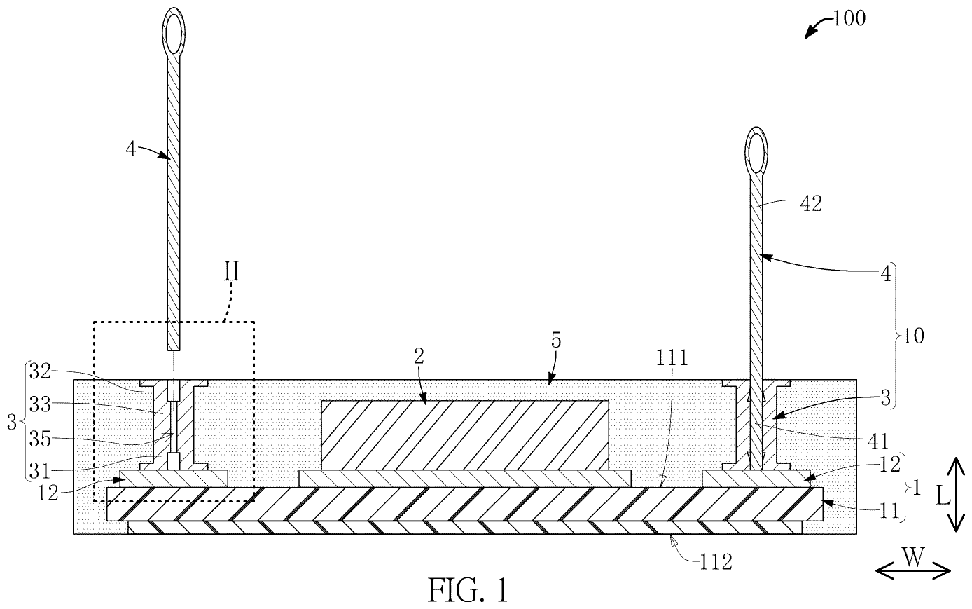

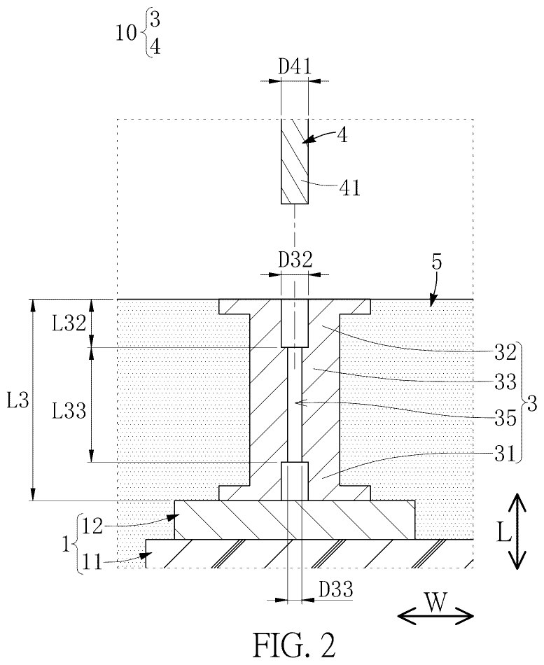

Referring to FIG. 1 to FIG. 5, a first embodiment of the present disclosure is provided. As shown in FIG. 1 and FIG. 2, the present embodiment provides a power component 100 having a pin insertion configuration, which includes a circuit board 1, at least one electronic member 2 mounted on the circuit board 1, a plurality of pin holders 3 disposed on the circuit board 1, a plurality of conductive pins 4 respectively inserted into the pin holders 3, and an encapsulant 5 that is formed on the circuit board 1.

It should be noted that each of the pin holders 3 and a corresponding one of the conductive pins 4 can be jointly defined as one of a plurality of signal transmission assemblies 10, and the signal transmission assemblies 10 of the power component 100 in the present embodiment are described in cooperation with the circuit board 1, the at least one electronic member 2, and the encapsulant 5, but the present disclosure is not limited thereto. For example, in other embodiments of the present disclosure not shown in the drawings, the signal transmission assembly 10 can be independently used (e.g., sold) or can be used in cooperation with other components; or, the encapsulant 5 and/or the at least one electronic member 2 can be omitted or can be replaced by other structures according to practical requirements.

In the present embodiment, the circuit board 1 includes a substrate 11 and a plurality of connection pads 12 that are disposed on the substrate 11. The substrate 11 has an inside surface 111 and an outside surface 112 that is opposite to the inside surface 111. The at least one electronic member 2 is mounted on the inside surface 111, the connection pads 12 are formed on the inside surface and are spaced apart from each other, and at least one of the connection pads 12 can be electrically coupled to the at least one electronic member 2 through the substrate 11.

It should be noted that a specific mode of the circuit board 1 can be adjusted or changed according to practical requirements. For example, the circuit board 1 can be a printed circuit board (PCB), a direct bonding copper (DBC) substrate, a direct plated copper (DPC) substrate, an active metal brazing (AMB) substrate, or other boards having circuit layout.

The pin holders 3 of the signal transmission assemblies 10 are mounted on and electrically coupled to the connection pads 12 of the circuit board 1, respectively. Moreover, as the signal transmission assemblies 10 in the present embodiment are of substantially the same structure, the following description discloses the structure of just one of the signal transmission assemblies 10 (i.e., one of the pin holders 3 and a corresponding one of the conductive pins 4) for the sake of brevity, but the present disclosure is not limited thereto. For example, in other embodiments of the present disclosure not shown in the drawings, the signal transmission assemblies 10 can be of different structures.

In the present embodiment, the pin holder 3 is integrally formed as a single one-piece tube structure and has a penetrating slot 35 along a longitudinal direction L thereof, and the pin holder 3 has a substantially round tube shape and has a total length L3 along the longitudinal direction L. The pin holder 3 has a connection end portion 31, an insertion end portion 32 arranged away from the connection end portion 31, and a positioning segment 33 that is arranged between the connection end portion 31 and the insertion end portion 32.

Specifically, the connection end portion 31 is fixed onto one of the connection pads 12, so that the pin holder 3 is erectly disposed on the circuit board 1. In other words, one end of the penetrating slot 35 arranged on the connection end portion 31 is enclosed by the corresponding connection pad 12. In addition, a connection between the connection end portion 31 and the corresponding connection pad 12 can be implemented in a soldering manner, but the present disclosure is not limited thereto.

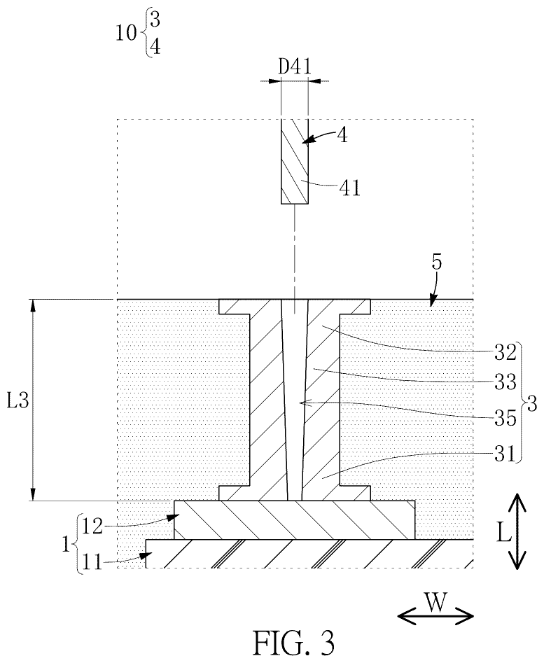

Moreover, the connection end portion 31 and the insertion end portion 32 shown in FIG. 2 of the present embodiment are mirror symmetrical to the positioning segment 33, but the present disclosure is not limited thereto. For example, as shown in FIG. 3, an inner diameter of the pin holder 3 can gradually decrease in a direction from the insertion end portion 32 toward the connection end portion 31 according to design requirements; or, in other embodiments of the present disclosure not shown in the drawings, a length of the connection portion 31 can be different from that of the insertion end portion 32.

As shown in FIG. 1 and FIG. 2, the insertion end portion 32 has a first length L32 along the longitudinal direction L and a first inner diameter D32 along a width direction W perpendicular to the longitudinal direction L. The positioning segment 33 has a second length L 33 along the longitudinal direction L and a second inner diameter D33 along the width direction W, the second length L33 is greater than the first length L32, and the second inner diameter D33 is less than the first inner diameter D32.

Specifically, the second length L33 is within a range from 40% to 80% of the total length L3, and the second inner diameter D33 is within a range from 85% to 95% of the first inner diameter D32. In other words, the second length L33 in the present embodiment can be within a range from 1 mm to 2.5 mm, and a difference between the second inner diameter D33 and the first inner diameter D32 can be within a range from 3 μm to 12 μm, but the present disclosure is not limited thereto.

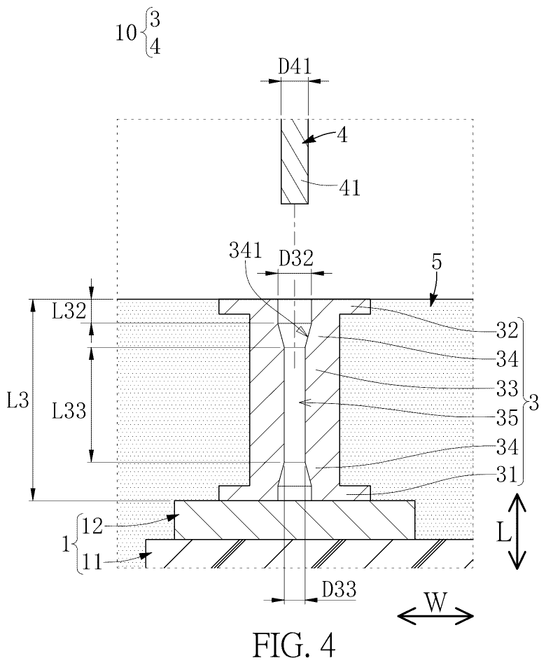

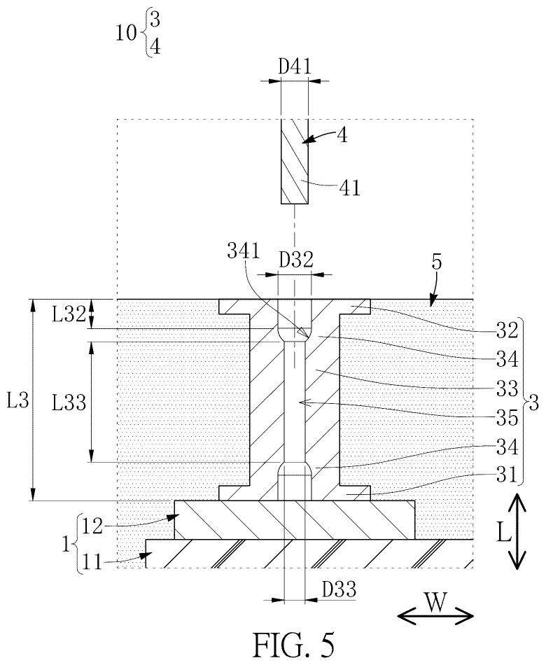

In addition, as shown in FIG. 2 and FIG. 3, two opposite ends of the positioning segment 33 can be respectively connected to the connection end portion 31 and the insertion end portion 32, but the present disclosure is not limited thereto. For example, as shown in FIG. 4 and FIG. 5, the pin holder 3 has a guiding segment 34 that connects the insertion end portion 32 and the positioning segment 33, and an inner diameter of the guiding segment 34 gradually decreases in a direction from the insertion end portion 32 toward the positioning segment 33. Furthermore, the pin holder 3 can be further provided with another one of the guiding segment 34 arranged between the connection end portion 31 and the positioning segment 33, but the present disclosure is not limited thereto.

Specifically, a shape of an inner surface 341 of the guiding segment 34 can be adjusted or changed according to design requirements. For example, as shown in FIG. 4, the inner surface 341 of the guiding segment 34 of the pin holder 3 can have a shape of a truncated cone; or, as shown in FIG. 5, the inner surface 341 of the guiding segment 34 of the pin holder 3 has a spherical shape having a center located in a space surrounded by the insertion end portion 32 or the guiding segment 34.

As shown in FIG. 1 and FIG. 2, the conductive pin 4 includes an insertion segment 41 and a fixing segment 42 that is connected to the insertion segment 41, and the insertion segment 41 has a rectangular prism shape and has a diagonal length D41 that is greater than the second inner diameter D33. In the present embodiment, an end of the insertion segment 41 can be a planar shape or a curved shaped, the diagonal length D41 of the insertion segment 41 can be slightly greater than or equal to the first inner diameter D32, and an end of the fixing segment 42 has a needle-like portion for being inserted into a corresponding hole of a printed circuit board (not shown in the drawings), but the present disclosure is not limited thereto.

In summary, the insertion segments 41 of the conductive pins 4 are respectively inserted into the positioning segments 33 of the pin holders 3 from the insertion end portions 32, such that each of the conductive pins 4 is electrically coupled to a corresponding one of the connection pads 12. The insertion segment 41 of each of the conductive pins 4 and the insertion end portion 32 of the corresponding pin holder 3 have a first interference value therebetween along the width direction W, and the insertion segment 41 of each of the conductive pins 4 and the positioning segment 33 of the corresponding pin holder 3 have a second interference value therebetween along the width direction W. The second interference value is greater than the first interference value.

Accordingly, the power component 100 in the present embodiment is provided with a structural cooperation between each of the pin holders 3 and the corresponding conductive pin 4, so that when the insertion segment 41 is inserted into the pin holder 3 (i.e., a pin insertion process), the insertion segment 41 is cooperated with the insertion end portion 32 by the smaller first interference value, and then the insertion segment 41 is further cooperated with the positioning segment 33 by the larger second interference value, thereby enabling the conductive pin 4 to firmly insert into the pin holder 3 and effectively preventing the conductive pin 4 from being bent in the pin insertion process.

In addition, the encapsulant 5 can be a molding compound or a solidified liquid compound according to practical requirements, and the circuit board 1 and the pin holders 3 are embedded in the encapsulant 5. The outside surface 112 of the circuit board 1 can be made of a metal material and is exposed from the encapsulant 5, thereby increasing a heat-dissipation efficiency of the circuit board 1.

Moreover, an end surface of the insertion end portion 32 of each of the pin holders 3 can be at least partially exposed from the encapsulant 5. Specifically, a surface of the encapsulant 5 away from the circuit board 1 is substantially flush with the end surfaces of the pin holders 3.

In other words, the encapsulant 5 of the present embodiment is formed on the circuit board 1 and the pin holders 3 before the conductive pins 4 are inserted into the pin holders 3.

### Second Embodiment

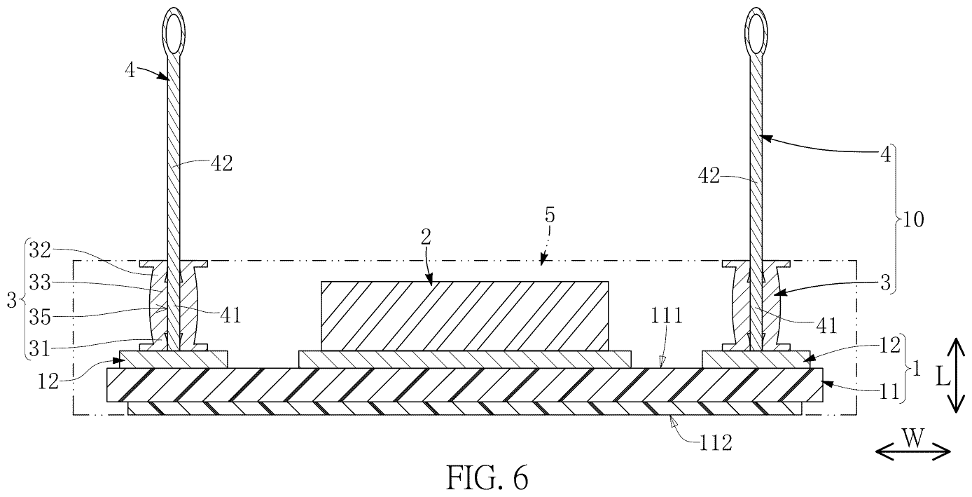

Referring to FIG. 6, a second embodiment of the present disclosure, which is similar to the first embodiment of the present disclosure, is provided. For the sake of brevity, descriptions of the same components in the first and second embodiments of the present disclosure will be omitted herein, and the following description only discloses different features between the first and second embodiments.

In the present embodiment, the encapsulant 5 is formed on the circuit board 1 and the pin holders 3 after the conductive pins 4 are inserted into the pin holders 3. The positioning segment 33 of each of the pin holders 3 has a deformation and a convex outer surface due to the second interference value. The encapsulant 5 covers the convex outer surfaces of the pin holders 3 and allows each of the pin holders 3 to have the deformation.

### Third Embodiment

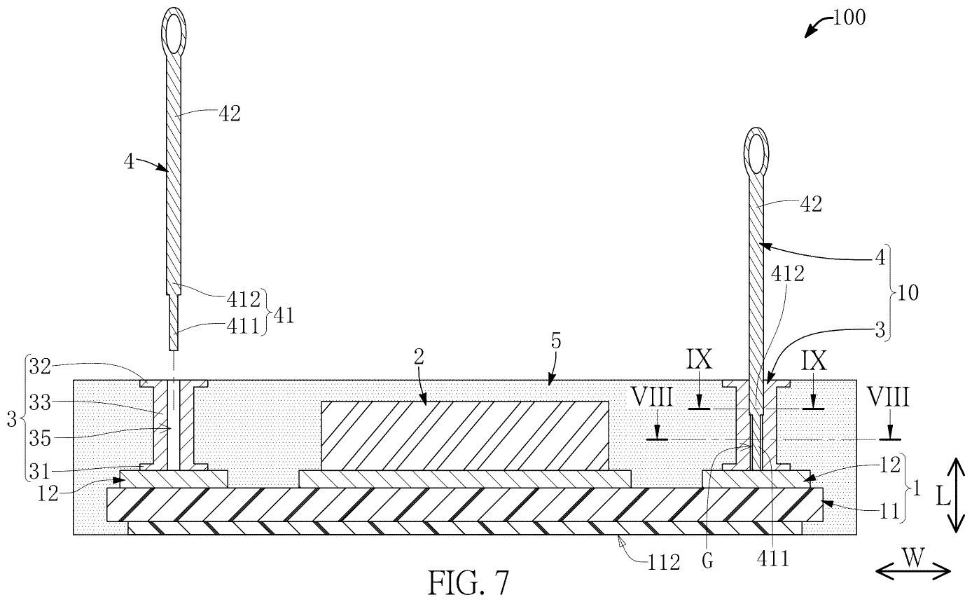

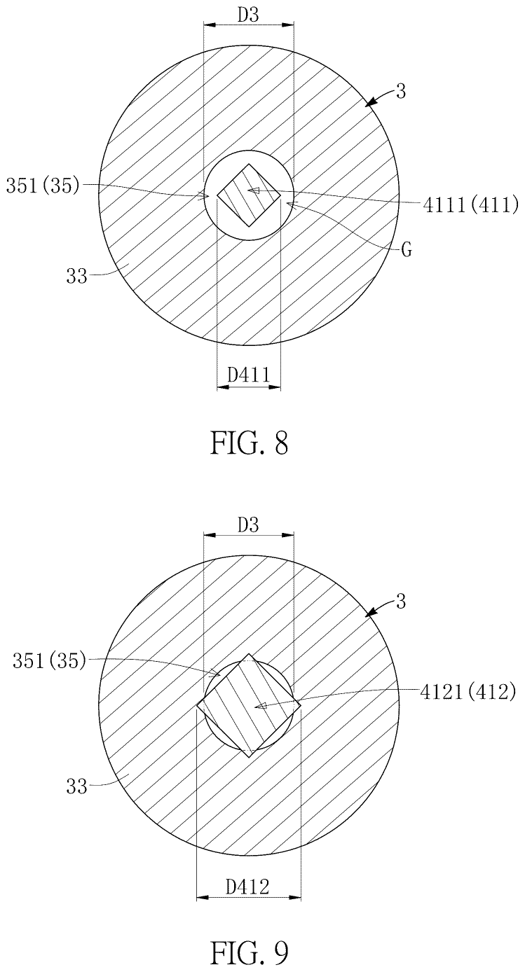

Referring to FIG. 7 to FIG. 10, a third embodiment of the present disclosure, which is similar to the first and second embodiments of the present disclosure, is provided. For the sake of brevity, descriptions of the same components in the first to third embodiments of the present disclosure will be omitted herein, and the following description only discloses different features among the first to third embodiments.

As shown in FIG, 7 to FIG. 9, the present embodiment provides a power component 100 having a pin insertion configuration, which includes a circuit board 1, at least one electronic member 2 mounted on the circuit board 1, a plurality of pin holders 3 disposed on the circuit board 1, a plurality of conductive pins 4 respectively inserted into the pin holders 3, and an encapsulant 5 that is formed on the circuit board 1.

It should be noted that each of the pin holders 3 and a corresponding one of the conductive pins 4 can be jointly defined as one of a plurality of signal transmission assemblies 10, and the signal transmission assemblies 10 of the power component 100 in the present embodiment are described in cooperation with the circuit board 1, the at least one electronic member 2, and the encapsulant 5, but the present disclosure is not limited thereto. For example, in other embodiments of the present disclosure not shown in the drawings, the signal transmission assembly 10 can be independently used (e.g., sold) or can be used in cooperation with other components; or, the encapsulant 5 and/or the at least one electronic member 2 can be omitted or can be replaced by other structures according to practical requirements.

In addition, since the circuit board 1 of the present embodiment is substantially identical to that of the first and second embodiments, descriptions of the circuit board 1 in the first to third embodiments will be omitted herein for the sake of brevity. Moreover, as the signal transmission assemblies 10 in the present embodiment are of substantially the same structure, the following description discloses the structure of just one of the signal transmission assemblies 10 (i.e., one of the pin holders 3 and a corresponding one of the conductive pins 4) for the sake of brevity, but the present disclosure is not limited thereto. For example, in other embodiments of the present disclosure not shown in the drawings, the signal transmission assemblies 10 can be of different structures.

In the present embodiment, the pin holder 3 is integrally formed as a single one-piece tube structure and has a penetrating slot 35 along a longitudinal direction L thereof. Moreover, the pin holder 3 has a substantially round tube shape and has an inner diameter of substantially the same value, and the penetrating slot 35 has a slot section 351 perpendicular to the longitudinal direction L. In other words, the slot sections 351 of any two portions of the penetrating slot 35 are substantially the same.

The pin holder 3 has a connection end portion 31, an insertion end portion 32 arranged away from the connection end portion 31, and a positioning segment 33 that is arranged between the connection end portion 31 and the insertion end portion 32. Furthermore, the connection end portion 31 is fixed onto one of the connection pads 12, so that the pin holder 3 is erectly disposed on the circuit board 1. In other words, one end of the penetrating slot 35 arranged on the connection end portion 31 is enclosed by the corresponding connection pad 12. In addition, a connection between the connection end portion 31 and the corresponding connection pad 12 can be implemented in a soldering manner, but the present disclosure is not limited thereto.

The conductive pin 4 includes an insertion segment 41 and a fixing segment 42 that is connected to the insertion segment 41. An end of the insertion segment 41 can be a planar shape or a curved shaped, and an end of the fixing segment 42 has a fisheye-like portion for being inserted into a corresponding hole of a printed circuit board (not shown in the drawings), but the present disclosure is not limited thereto.

Accordingly, the insertion segments 41 of the conductive pins 4 are respectively inserted into the positioning segments 33 of the pin holders 3 from the insertion end portions 32, such that each of the conductive pins 4 is electrically coupled to a corresponding one of the connection pads 12 by using the insertion segment 41 to be connected to the pin holder 3.

Specifically, the insertion segment 41 of the conductive pin 4 has a front sub-segment 411 and a rear sub-segment 412 that is connected in-between the front sub-segment 411 and the fixing segment 42. It should be noted that the front sub-segment 411 and the rear sub-segment 412 can be connected to each other through a slanting surface therebetween for enabling the inserting segment 41 to easily insert into the pin holder 3, but the present disclosure is not limited thereto.

Moreover, the front sub-segment 411 has a front section 4111 that is perpendicular to the longitudinal direction L and that is smaller than the slot section 351. The slot section 351 of the penetrating slot 35 and the front section 4111 of the front sub-segment 411 each have a circular shape, and an inner diameter D3 of the pin holder 3 is greater than or equal to a first diagonal length D411 of the front sub-segment 411 (e.g., the first diagonal length D411 is within a range from 60% to 100% of the inner diameter D3). In other words, the front sub-segment 411 of the insertion segment 41 and the corresponding pin holder 3 can have a gap G therebetween along a width direction W perpendicular to the longitudinal direction L (i.e., the front sub-segment 411 and the corresponding pin holder 3 have no interference force therebetween). Accordingly, in a pin insertion process of the conductive pin 4, the front sub-segment 411 can be in cooperation with the corresponding pin holder 3 for eliminating lateral stress, thereby enabling the insertion segment 41 to smoothly and entirely insert into the pin holder 3.

In addition, the rear sub-segment 412 has a rear section 4121 that is perpendicular to the longitudinal direction L and that is greater than the slot section 351. The rear section 4121 has a rectangular or polygonal shape, the rear sub-segment 412 has a second diagonal length D412 being greater than the first diagonal length D411, and the inner diameter D3 of the pin holder 3 is less than or equal to the second diagonal length D412 (e.g., the second diagonal length D412 is within a range from 100% to 150% of the inner diameter D3). Accordingly, the rear sub-segment 412 of the insertion segment 41 of the conductive pin 4 and the corresponding pin holder 3 have an interference value therebetween along the width direction W (e.g., corners of the polygon shape of the rear section 4121 are in interference with the slot section 351).

In summary, the power component 100 in the present embodiment is provided with a structural cooperation between each of the pin holders 3 and the corresponding conductive pin 4, so that when the insertion segment 41 is inserted into the pin holder 3 (i.e., the pin insertion process), the front sub-segment 411 is cooperated with the pin holder 3 for jointly forming the gap G, and then the rear sub-segment 412 is interfered with the pin holder 3, thereby enabling the conductive pin 4 to be firmly inserted into the pin holder 3 and effectively preventing the conductive pin 4 from being bent in the pin insertion process.

In addition, the encapsulant 5 can be a molding compound or a solidified liquid compound according to practical requirements, and the circuit board 1 and the pin holders 3 are embedded in the encapsulant 5. The outside surface 112 of the circuit board 1 can be made of a metal material and is exposed from the encapsulant 5, thereby increasing a heat-dissipation efficiency of the circuit board 1.

Moreover, an end surface of the insertion end portion 32 of each of the pin holders 3 can be at least partially exposed from the encapsulant 5. Specifically, a surface of the encapsulant 5 away from the circuit board 1 is substantially flush with the end surfaces of the pin holders 3.

In other words, the encapsulant 5 of the present embodiment is formed on the circuit board 1 and the pin holders 3 before the conductive pins 4 are inserted into the pin holders 3.

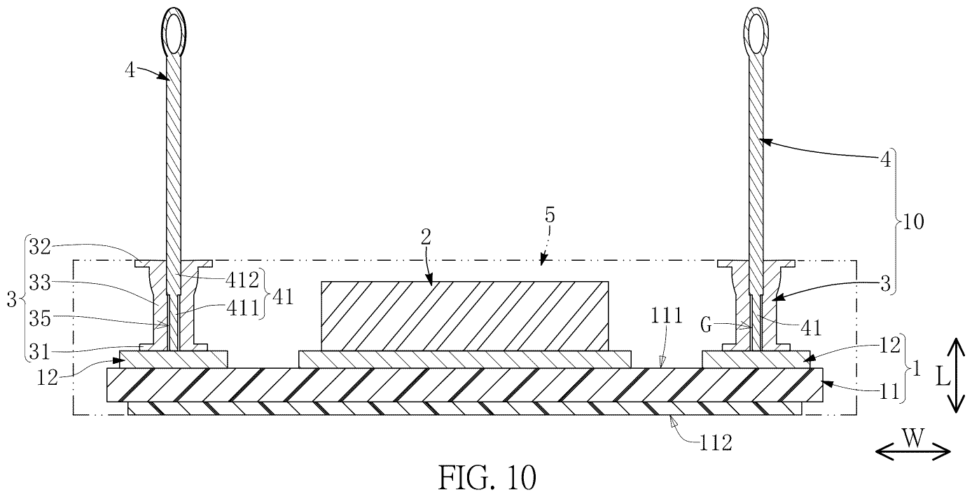

Moreover, as shown in FIG. 10, the encapsulant 5 is formed on the circuit board 1 and the pin holders 3 after the conductive pins 4 are inserted into the pin holders 3. Each of the pin holders 3 has a deformation and a convex outer surface due to the interference value. The encapsulant 5 covers the convex outer surfaces of the pin holders 3 and allows each of the pin holders 3 to have the deformation.

It should be noted that, in other embodiments of the present disclosure not shown in the drawings, the signal transmission assembly 10 can be provided with the pin holder 3 of the first embodiment and the conductive pin 4 of the second embodiment according to practical requirements.

### Beneficial Effects of the Embodiments

In conclusion, the power component of the present disclosure is provided with a structural cooperation between each of the pin holders and the corresponding conductive pin, so that when the insertion segment is inserted into the pin holder (i.e., a pin insertion process), an interference between the insertion segment and the pin holder can be gradually increased (e.g., the insertion segment is cooperated with the insertion end portion by the smaller first interference value, and then the insertion segment is further cooperated with the positioning segment by the larger second interference value; or, the front sub-segment is cooperated with the pin holder for jointly forming the gap, and then the rear sub-segment is interfered with the pin holder), thereby enabling the conductive pin to firmly insert into the pin holder and effectively preventing the conductive pin from being bent in the pin insertion process.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A power component having a pin insertion configuration, comprising:
a circuit board having a plurality of connection pads;
a plurality of pin holders each being integrally formed as a single one-piece tube structure and having a penetrating slot along a longitudinal direction thereof, wherein each of the pin holders has:
a connection end portion fixed onto one of the connection pads;
an insertion end portion arranged away from the connection end portion, wherein the insertion end portion has a first length along the longitudinal direction and a first inner diameter along a width direction perpendicular to the longitudinal direction; and
a positioning segment arranged between the connection end portion and the insertion end portion, wherein the positioning segment has a second length along the longitudinal direction and a second inner diameter along the width direction, and wherein the second length is greater than the first length, and the second inner diameter is less than the first inner diameter; and
a plurality of conductive pins each including an insertion segment and a fixing segment that is connected to the insertion segment, wherein the insertion segments of the conductive pins are respectively inserted into the positioning segments of the pin holders from the insertion end portions, such that each of the conductive pins is electrically coupled to a corresponding one of the connection pads;
wherein the insertion segment of each of the conductive pins and the insertion end portion of the corresponding pin holder optionally have a first interference value therebetween along the width direction, and the insertion segment of each of the conductive pins and the positioning segment of the corresponding pin holder have a second interference value therebetween along the width direction, and wherein the second interference value is greater than the first interference value.

2. The power component according to claim 1, wherein each of the pin holders has a guiding segment that connects the insertion end portion and the positioning segment, and an inner diameter of the guiding segment gradually decreases in a direction from the insertion end portion toward the positioning segment.

3. The power component according to claim 2, wherein, in each of the pin holders, an inner surface of the guiding segment has a shape of a truncated cone.

4. The power component according to claim 2, wherein, in each of the pin holders, an inner surface of the guiding segment has a spherical shape having a center located in a space surrounded by the insertion end portion or the guiding segment.

5. The power component according to claim 1, wherein an inner diameter of each of the pin holders gradually decreases in a direction from the insertion end portion toward the connection end portion.

6. The power component according to claim 1, wherein each of the pin holders has a total length along the longitudinal direction, and the second length is within a range from 40% to 80% of the total length.

7. The power component according to claim 1, wherein the insertion segment of each of the conductive pins has a diagonal length being greater than the second inner diameter, and wherein, in each of the pin holders, the second inner diameter is within a range from 85% to 95% of the first inner diameter.

8. The power component according to claim 1, further comprising an encapsulant, wherein the circuit board and the pin holders are embedded in the encapsulant, and the fixing segment of each of the conductive pins is not in contact with the encapsulant.

9. The power component according to claim 8, wherein a surface of the encapsulant away from the circuit board is flush with end surfaces of the pin holders.

10. The power component according to claim 1, further comprising an encapsulant, wherein the circuit board and the pin holders are embedded in the encapsulant, and the positioning segment of each of the pin holders has a deformation and a convex outer surface due to the second interference value.

11. A signal transmission assembly of a power component, comprising:
a pin holder integrally formed as a single one-piece tube structure and having a penetrating slot along a longitudinal direction thereof, wherein the pin holder has:
a connection end portion;
an insertion end portion arranged away from the connection end portion, wherein the insertion end portion has a first length along the longitudinal direction and a first inner diameter along a width direction perpendicular to the longitudinal direction; and
a positioning segment arranged between the connection end portion and the insertion end portion, wherein the positioning segment has a second length along the longitudinal direction and a second inner diameter along the width direction, and wherein the second length is greater than the first length, and the second inner diameter is less than the first inner diameter; and
a conductive pin including an insertion segment and a fixing segment that is connected to the insertion segment, wherein the insertion segment of the conductive pin is inserted into the positioning segment of the pin holder from the insertion end portion;
wherein the insertion segment of the conductive pin and the insertion end portion of the pin holder have a first interference value therebetween along the width direction, and the insertion segment of the conductive pin and the positioning segment of the pin holder have a second interference value therebetween along the width direction, and wherein the second interference value is greater than the first interference value.

12. The signal transmission assembly according to claim 11, wherein the pin holder has a total length along the longitudinal direction, and the second length is within a range from 40% to 80% of the total length, and wherein the insertion segment of the conductive pin has a diagonal length being greater than the second inner diameter, and the second inner diameter is within a range from 85% to 95% of the first inner diameter.

13. A power component having a pin insertion configuration, comprising:
a circuit board having a plurality of connection pads;
a plurality of pin holders each being integrally formed as a single one-piece tube structure and having a penetrating slot along a longitudinal direction thereof, wherein the penetrating slot of each of the pin holders has a slot section perpendicular to the longitudinal direction, and each of the pin holders has:
a connection end portion fixed onto one of the connection pads;
an insertion end portion arranged away from the connection end portion; and
a positioning segment arranged between the connection end portion and the insertion end portion; and
a plurality of conductive pins each including an insertion segment and a fixing segment that is connected to the insertion segment, wherein the insertion segments of the conductive pins are respectively inserted into the positioning segments of the pin holders from the insertion end portions, such that each of the conductive pins is electrically coupled to a corresponding one of the connection pads, wherein the insertion segment of each of the conductive pins has:
front sub-segment having a front section that is perpendicular to the longitudinal direction and that is smaller than the slot section; and
a rear sub-segment connected to the front sub-segment and having a rear section that is perpendicular to the longitudinal direction and that is larger than the slot section;
wherein the front sub-segment of the insertion segment of each of the conductive pins and the corresponding pin holder have a gap therebetween along a width direction perpendicular to the longitudinal direction, and the rear sub-segment of the insertion segment of each of the conductive pins and the corresponding pin holder have an interference value therebetween along the width direction.

14. The power component according to claim 13, wherein, in each of the conductive pins, the front sub-segment has a first diagonal length, and the rear sub-segment has a second diagonal length being greater than the first diagonal length, and wherein, in each of the conductive pins and the corresponding pin holder, an inner diameter of the pin holder is greater than the first diagonal length and is less than the second diagonal length.

15. The power component according to claim 14, wherein, in each of the conductive pins and the corresponding pin holder, the first diagonal length is within a range from 60% to 100% of the inner diameter, and the second diagonal length is within a range from 100% to 150% of the inner diameter.

16. The power component according to claim 13, wherein, in each of the conductive pins and the corresponding pin holder, each of the slot section and the front section has a circular shape, the rear section has a polygonal shape, and corners of the polygonal shape of the rear section are in interference with the slot section.

17. The power component according to claim 13, further comprising an encapsulant, wherein the circuit board and the pin holders are embedded in the encapsulant, and the fixing segment of each of the conductive pins is not in contact with the encapsulant.

18. The power component according to claim 17, wherein a surface of the encapsulant away from the circuit board is flush with end surfaces of the pin holders.
